(19) United States
(12) Patent Application Publication
(10) Pub. No.: US 2025/0351469 A1
(43) Pub. Date: Nov. 13, 2025

(54) SEMICONDUCTOR DEVICE

(71) Applicant: Mitsubishi Electric Corporation, Tokyo (JP)

(72) Inventor: Shunsuke SAKAMOTO, Fukuoka (JP)

(73) Assignee: Mitsubishi Electric Corporation, Tokyo (JP)

(21) Appl. No.: 19/071,187

(22) Filed: Mar. 5, 2025

(30) Foreign Application Priority Data
May 9, 2024 (JP) 2024-076260

(51) Int. Cl. H10D 62/10; H10D 64/00; H10D 64/27; H10D 64/60

(52) U.S. Cl. CPC H10D 62/102; H10D 64/112; H10D 64/529; H10D 64/60

(57) ABSTRACT

An object is to provide a semiconductor device that enhances the reliability under high temperature and high humidity. The semiconductor device includes a semiconductor substrate, a first electrode, an insulating interlayer film, and at least one second electrode. The semiconductor substrate includes an active region through which a main current flows, and a termination region formed around the active region. The first electrode is formed in the active region. The insulating interlayer film is formed in the termination region on a front surface side of the semiconductor substrate. The at least one second electrode is formed in the termination region to annularly surround the active region. A part of the at least one second electrode is buried in the insulating interlayer film. A lower surface of the at least one second electrode is located below an upper surface of the insulating interlayer film.

### BACKGROUND

### Technical Field

The present disclosure relates to a semiconductor device.

### Description of the Background Art

The need for thermal humidity bias (THB) tests is increasing to enhance the reliability of power devices. Structures of termination regions formed in the power devices affect characteristics of the THB tests. In a termination region of a semiconductor device described in Japanese Patent Application Laid-Open No. 2015-76544, the second field plate is formed on the upper surface of the second insulating film.

The shapes and film qualities of electrodes and insulating films formed in the termination region greatly affect the characteristics of the THB tests. For example, moisture easily intrudes into an inner portion of a device from a thin protective film under high temperature and high humidity conditions. The intruded moisture corrodes the electrodes in the termination region, and shortens the life of the power device.

### SUMMARY

An object of the present disclosure is to provide a semiconductor device that enhances the reliability under high temperature and high humidity.

The semiconductor device according to the present disclosure includes a semiconductor substrate, a first electrode, an insulating interlayer film, and at least one second electrode. The semiconductor substrate includes an active region through which a main current flows, and a termination region formed around the active region. The first electrode is formed in the active region. The insulating interlayer film is formed in the termination region on a front surface side of the semiconductor substrate. The at least one second electrode is formed in the termination region to annularly surround the active region. A part of the at least one second electrode is buried in the insulating interlayer film. A lower surface of the at least one second electrode is located below an upper surface of the insulating interlayer film.

The semiconductor device that enhances the reliability under high temperature and high humidity will be provided.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view illustrating a structure of a semiconductor device according to Embodiment 1;

FIG. 2 is a cross-sectional view illustrating a structure of a semiconductor device according to a modification of Embodiment 1;

FIG. 3 is a cross-sectional view illustrating a structure of a semiconductor device according to Embodiment 5; and

FIG. 4 is a cross-sectional view illustrating a structure of a semiconductor device according to a modification of Embodiment 5.

### DESCRIPTION OF THE PREFERRED EMBODIMENTS

### Embodiment 1

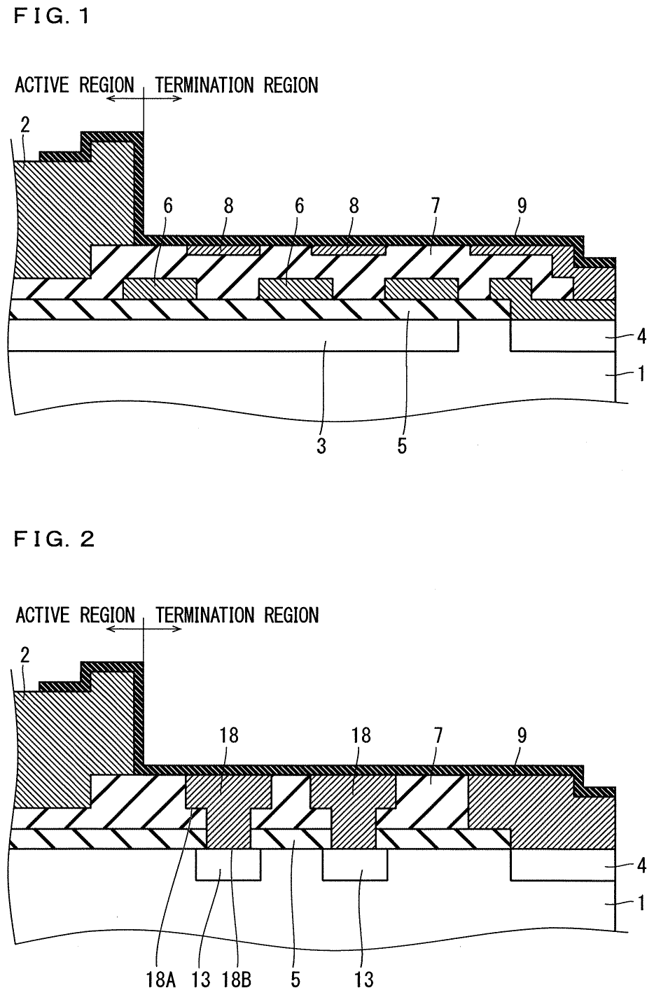

FIG. 1 is a cross-sectional view illustrating a structure of a semiconductor device according to Embodiment 1. FIG. 1 illustrates an upper cross-sectional structure of the semiconductor device, and omits a lower cross-sectional structure thereof. The semiconductor device includes a semiconductor substrate 1 including an active region and a termination region. In a plan view of the semiconductor device, the termination region is formed around the active region to surround the active region of which illustration is omitted.

The semiconductor device includes a semiconductor element (not illustrated) and a first electrode 2 in the active region. The semiconductor element is formed inside the semiconductor substrate 1. The semiconductor element is made of, for example, a semiconductor such as Si. The semiconductor element may be made of, for example, a wide bandgap semiconductor such as SiC. The semiconductor element is a switching element such as an insulated-gate bipolar transistor (IGBT) or a metal-oxide-semiconductor field effect transistor (MOSFET), or a Schottky barrier diode. The first electrode 2 is formed on a front surface side of the semiconductor substrate 1, and is electrically connected to the semiconductor element. When the semiconductor element is an IGBT, the first electrode 2 is an emitter electrode, and a main current flows between the emitter and the collector of the IGBT through the first electrode 2. In other words, the main current flows through the first electrode 2 in the active region.

In the termination region according to Embodiment 1, a reduced surface field (RESURF) structure is formed. In the termination region, the semiconductor device includes a p-type semiconductor layer 3, an n-type semiconductor layer 4, an oxide film 5, a conductive film 6, an insulating interlayer film 7, second electrodes 8, and a protective film 9.

The p-type semiconductor layer 3 and the n-type semiconductor layer 4 are formed as a surface layer of the semiconductor substrate 1. The p-type semiconductor layer 3 is formed closer to the active region than the n-type semiconductor layer 4. The oxide film 5 is formed on the upper surface of the p-type semiconductor layer 3. The conductive film 6 is selectively formed on the oxide film 5 in the termination region. The conductive film 6 is, for example, a polysilicon film.

The insulating interlayer film 7 is formed on the front surface side of the semiconductor substrate 1. The insulating interlayer film 7 in Embodiment 1 is formed between the conductive film 6 and the second electrodes 8 to cover the oxide film 5 and the conductive film 6 formed on the oxide film 5.

The second electrodes 8 are field plate electrodes. In a plan view, the two second electrodes 8 are formed to annularly surround the active region of which illustration is omitted. As illustrated in FIG. 1, the upper surface of each of the second electrodes 8 is exposed from the upper surface of the insulating interlayer film 7. Here, the upper surface of the insulating interlayer film 7 is a surface of the insulating interlayer film 7 in contact with the protective film 9. The upper surface of each of the second electrodes 8 is identical in height to the upper surface of the insulating interlayer film 7. In other words, the upper surface of each of the second electrodes 8 is flush with the upper surface of the insulating interlayer film 7. the height of the upper surface of each of the second electrodes 8 and the insulating interlayer film 7 corresponds to, for example, a height from the front surface of the semiconductor substrate 1. The side surface and the lower surface of each of the second electrodes 8 are buried in the insulating interlayer film 7. In other words, parts of the second electrodes 8 are buried in the insulating interlayer film 7, and the lower surface of each of the second electrodes 8 is located below the upper surface of the insulating interlayer film 7.

The protective film 9 is formed to cover the upper surface of the insulating interlayer film 7 and the upper surface of each of the second electrodes 8.

When a difference in height between the upper surface of each of the second electrodes 8 and the upper surface of the insulating interlayer film 7 is large, the protective film 9 covering the corners of the second electrodes 8 is locally thinned. Thus, for example, moisture intrudes from a thin portion of the protective film 9 under high temperature and high humidity conditions. This causes corrosion in the second electrodes 8 in the termination region to change the shape of the second electrodes 8. Consequently, a designed electric field cannot be retained inside the semiconductor substrate 1. This causes an increase in the leakage current and a decrease in the breakdown voltage.

In the semiconductor device according to Embodiment 1, however, bottoms of the second electrodes 8 are buried in the insulating interlayer film 7, and the lower surface of each of the second electrodes 8 is lower than the upper surface of the insulating interlayer film 7. This increases the flatness of the protective film 9 covering the second electrodes 8 and the insulating interlayer film 7, and improves the uniformity of the film thickness of the protective film 9. Consequently, the infiltration of, for example, moisture from the protective film 9 to the second electrodes 8 can be prevented even under high temperature and high humidity conditions. Since this can reduce changes in shape of the second electrodes 8 due to corrosion and suppress a decrease in the insulating properties of the semiconductor device, the life of the semiconductor device will be increased.

Although the semiconductor device according to Embodiment 1 includes the two second electrodes 8, the number of the second electrodes 8 is not limited to two. The semiconductor device according to Embodiment 1 should include at least one second electrode 8. When the semiconductor device according to Embodiment 1 includes a plurality of second electrodes 8, the second electrodes 8 need not have the same layout of, for example, an electrode width.

To sum up, the semiconductor device according to Embodiment 1 includes the semiconductor substrate 1, the first electrode 2, the insulating interlayer film 7, and the at least one second electrode 8. The semiconductor substrate 1 includes the active region through which a main current flows, and the termination region formed around the active region. The first electrode 2 is formed in the active region. The insulating interlayer film 7 is formed on a front surface side of the semiconductor substrate 1 in the termination region. The at least one second electrode 8 is formed in the termination region to annularly surround the active region. A part of the at least one second electrode 8 is buried in the insulating interlayer film 7. A lower surface of the at least one second electrode 8 is located below an upper surface of the insulating interlayer film 7.

In such a semiconductor device, variations in electrical characteristics under high temperature and high humidity conditions will be reduced, and the reliability will be enhanced.

### Modifications of Embodiment 1

FIG. 2 is a cross-sectional view illustrating a structure of a semiconductor device according to a modification of Embodiment 1. FIG. 2 illustrates an upper cross-sectional structure of the semiconductor device, and omits a lower cross-sectional structure thereof.

In the termination region according to the modification of Embodiment 1, a field limiting ring (FLR) structure is formed. In the termination region, the semiconductor device includes a p-type semiconductor layer 13, the n-type semiconductor layer 4, the oxide film 5, the insulating interlayer film 7, second electrodes 18, and the protective film 9.

The p-type semiconductor layer 13 and the n-type semiconductor layer 4 are formed as a surface layer of the semiconductor substrate 1. The p-type semiconductor layer 13 is selectively formed in the surface layer of the semiconductor substrate 1 in the termination region. Furthermore, the p-type semiconductor layer 13 is formed closer to the active region than the n-type semiconductor layer 4. The oxide film 5 is formed on the front surface of the semiconductor substrate 1.

The insulating interlayer film 7 is formed between the oxide film 5 and the protective film 9.

In a plan view, the two second electrodes 18 are formed to annularly surround the active region of which illustration is omitted. As illustrated in FIG. 2, the upper surface of each of the second electrodes 18 is exposed from the upper surface of the insulating interlayer film 7. The upper surface of each of the second electrodes 18 is identical in height to the upper surface of the insulating interlayer film 7. In other words, the upper surface of each of the second electrodes 18 is flush with the upper surface of the insulating interlayer film 7. Each of the two second electrodes 18 is T-shaped in a cross-sectional view, and has a first lower surface 18A and a second lower surface 18B. The second electrodes 18 penetrate the insulating interlayer film 7 and the oxide film 5. The side surface and the first lower surface 18A of each of the second electrodes 18 are buried in the insulating interlayer film 7. The second lower surface 18B is in contact with the p-type semiconductor layer 13. As such, a part of the second electrodes 18 is buried in the insulating interlayer film 7, and the first lower surface 18A and the second lower surface 18B of each of the second electrodes 18 are located below the upper surface of the insulating interlayer film 7.

The protective film 9 is formed to cover the upper surface of the insulating interlayer film 7 and the upper surface of each of the second electrodes 18.

Even such a structure increases the flatness of the protective film 9 covering the second electrodes 18 and the insulating interlayer film 7, and improves the uniformity of the film thickness of the protective film 9. Consequently, the infiltration of, for example, moisture from the protective film 9 to the second electrodes 18 can be prevented even under high temperature and high humidity conditions. Since this can reduce changes in shape of the second electrodes 18 due to corrosion and suppress a decrease in the insulating properties of the semiconductor device, the life of the semiconductor device will be increased.

Although the semiconductor device according to the modification of Embodiment 1 includes the two second electrodes 18, the number of the second electrodes 18 is not limited to two. The semiconductor device according to the modification should include at least one second electrode 18. When the semiconductor device includes a plurality of second electrodes 18, the second electrodes 18 need not have the same layout of, for example, an electrode width.

Although Embodiment 1 and its modification describe the RESURF structure and the FLR structure, respectively, the structure of the termination region is not limited to these. As long as a semiconductor device has a structure in which parts of the second electrodes 8 or 18 are buried in the insulating interlayer film 7 and the lower surface of each of the second electrodes 8 or 18 is located below the upper surface of the insulating interlayer film 7, the semiconductor device produces the same advantages as described above.

### Embodiment 2

In FIG. 1 and FIG. 2, the upper surfaces of the second electrodes 8 and the second electrodes 18, respectively, may be higher than the upper surface of the insulating interlayer film 7. In such a case, a difference in height between the upper surface of each of the second electrodes 8 or 18 and the upper surface of the insulating interlayer film 7 is preferably less than or equal to the thickness of the protective film 9. This increases the flatness of the protective film 9, and produces the same advantages as described above.

### Embodiment 3

Although the semiconductor device in FIG. 1 or 2 includes the two second electrodes 8 or 18, the number of the second electrodes 8 or 18 is not limited to two. All the second electrodes 8 or 18 need not have the same layout of, for example, an electrode width.

### Embodiment 4

The second electrodes 8 and 18 are made of a material different from that of the first electrode 2. The first electrode 2 and the second electrodes 8 and 18 contain at least one material of Ti, Cr, W, and Mo. Forming the second electrodes 8 and 18 with a highly corrosive material mitigates a decrease in the insulating properties of the semiconductor device.

The second electrodes 8 and 18 may be made of a material identical to that of the first electrode 2. Since this can simultaneously form the first electrode 2 and the second electrodes 8 and 18, the cost can be reduced.

### Embodiment 5

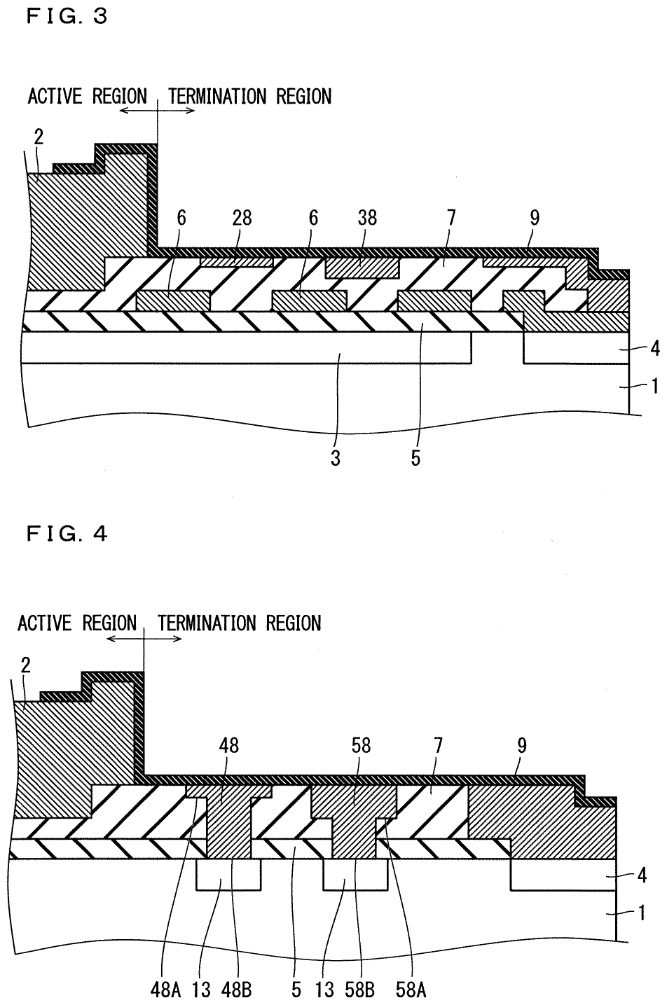

FIG. 3 is a cross-sectional view illustrating a structure of a semiconductor device according to Embodiment 5. FIG. 3 illustrates an upper cross-sectional structure of the semiconductor device, and omits a lower cross-sectional structure thereof. In the termination region, a RESURF structure is formed.

Two second electrodes 28 and 38 have lower surfaces different in height from the front surface of the semiconductor substrate 1. In other words, the lower surface of the second electrode 28 differs in height from the lower surface of the second electrode 38. The semiconductor device should include the insulating interlayer film 7 in any region. The difference in height between the lower surfaces of the second electrodes 28 and 38 optimizes the electric field intensity distribution occurring in the semiconductor substrate 1. As a result, a decrease in the insulating properties of the semiconductor device will be further mitigated.

Each of the two second electrodes 28 and 38 contains at least one material of Ti, Cr, W, and Mo. Forming the second electrodes 28 and 38 with a highly corrosive material mitigates a decrease in the insulating properties of the semiconductor device.

### Modifications of Embodiment 5

FIG. 4 is a cross-sectional view illustrating a structure of a semiconductor device according to a modification of Embodiment 5. FIG. 4 illustrates an upper cross-sectional structure of the semiconductor device, and omits a lower cross-sectional structure thereof. In the termination region, an FLR structure is formed.

Each of the two second electrodes 48 and 58 is T-shaped in a cross-sectional view. The second electrode 48 has a first lower surface 48A and a second lower surface 48B. The second electrode 58 has a first lower surface 58A and a second lower surface 58B. The second electrodes 48 and 58 penetrate the insulating interlayer film 7 and the oxide film 5. The side surface and the first lower surface 48A of the second electrode 48 are buried in the insulating interlayer film 7. Similarly, the side surface and the first lower surface 58A of the second electrode 58 are buried in the insulating interlayer film 7. The second lower surface 48B and the second lower surface 58B are in contact with the p-type semiconductor layer 13. The first lower surface 48A and the first lower surface 58A are different in height from the front surface of the semiconductor substrate 1. In other words, the second electrode 48 and the second electrode 58 have the first lower surface 48A and the first lower surface 58A, respectively, which are different in height from the front surface of the semiconductor substrate 1. The semiconductor device should include the insulating interlayer film 7 in any region. Each of the two second electrodes 48 and 58 contains at least one material of Ti, Cr, W, and Mo. Such a structure also produces the same advantages as described above.

### Embodiment 6

A method of forming the second electrodes 8 and the second electrodes 18 illustrated in FIG. 1 and FIG. 2, respectively, will be described. After the insulating interlayer film 7 is formed, recesses are formed in predetermined regions using a photolithography (lithography) technique and an etching technique.

### Embodiment 7

When the first electrode 2 and the second electrodes 8 or 18 are formed of the same material in Embodiment 6, first, an electrode film for forming the first electrode 2 and the second electrodes 8 or 18 is formed by, for example, sputtering or vapor deposition. Then, a pattern of exposing only the termination region is formed by photolithography. Then, the electrode film is processed by etching to have a desired film thickness. Furthermore, a pattern of exposing only the active region is formed by photolithography. The active region is etched to form the first electrode 2 and the second electrodes 8 or 18 with different heights.

### Embodiment 8

When the first electrode 2 and the second electrodes 8 or 18 are formed of different materials in Embodiment 6, first, an electrode film to be the second electrodes 8 or 18 is formed with a desired height by, for example, sputtering or vapor deposition. Then, a pattern of exposing only the active region is formed by photolithography. Next, the electrode film is removed by etching. Furthermore, an electrode film to be the first electrode 2 is formed by, for example, sputtering or vapor deposition. Then, a pattern of exposing only the termination region is formed by photolithography. Next, the electrode film is removed by etching. This forms the first electrode 2 and the second electrodes 8 or 18 which have different heights and are made of different materials.

Embodiments can be freely combined, and appropriately modified or omitted.

A summary of various aspects of the present disclosure will be hereinafter described as Appendixes.

### Appendix 1

A semiconductor device, comprising:
a semiconductor substrate including an active region through which a main current flows, and a termination region formed around the active region;
a first electrode formed in the active region;
an insulating interlayer film formed in the termination region on a front surface side of the semiconductor substrate; and
at least one second electrode formed in the termination region to annularly surround the active region,
wherein a part of the at least one second electrode is buried in the insulating interlayer film, and
a lower surface of the at least one second electrode is located below an upper surface of the insulating interlayer film.

### Appendix 2

The semiconductor device according to appendix 1, further comprising
a protective film covering the upper surface of the insulating interlayer film, wherein an upper surface of the at least one second electrode is exposed from the upper surface of the insulating interlayer film, and is covered with the protective film.

### Appendix 3

The semiconductor device according to appendix 1 or 2,
wherein the at least one second electrode is made of a material different from a material of the first electrode, and contains at least one material of Ti, Cr, W, and Mo.

### Appendix 4

The semiconductor device according to appendix 1 or 2,
wherein the at least one second electrode is made of a material identical to a material of the first electrode.

### Appendix 5

The semiconductor device according to any one of appendixes 1 to 4,
wherein an upper surface of the at least one second electrode is identical in height to the upper surface of the insulating interlayer film.

### Appendix 6

The semiconductor device according to any one of appendixes 1 to 5,
wherein the at least one second electrode comprises a plurality of second electrodes, and
the plurality of second electrodes have lower surfaces different in height from a front surface of the semiconductor substrate.

### Appendix 7

The semiconductor device according to appendix 6,
wherein each of the plurality of second electrodes contains at least one material of Ti, Cr, W, and Mo.

While the disclosure has been shown and described in detail, the foregoing description is in all aspects illustrative and not restrictive. It is therefore understood that numerous modifications and variations can be devised.

What is claimed is:

1. A semiconductor device, comprising:
a semiconductor substrate including an active region through which a main current flows, and a termination region formed around the active region;
a first electrode formed in the active region;
an insulating interlayer film formed in the termination region on a front surface side of the semiconductor substrate; and
at least one second electrode formed in the termination region to annularly surround the active region,
wherein a part of the at least one second electrode is buried in the insulating interlayer film, and
a lower surface of the at least one second electrode is located below an upper surface of the insulating interlayer film.

2. The semiconductor device according to claim 1, further comprising
a protective film covering the upper surface of the insulating interlayer film,
wherein an upper surface of the at least one second electrode is exposed from the upper surface of the insulating interlayer film, and is covered with the protective film.

3. The semiconductor device according to claim 1,
wherein the at least one second electrode is made of a material different from a material of the first electrode, and contains at least one material of Ti, Cr, W, and Mo.

4. The semiconductor device according to claim 1,
wherein the at least one second electrode is made of a material identical to a material of the first electrode.

5. The semiconductor device according to claim 1,
wherein an upper surface of the at least one second electrode is identical in height to the upper surface of the insulating interlayer film.

6. The semiconductor device according to claim 1,
wherein the at least one second electrode comprises a plurality of second electrodes, and
the plurality of second electrodes have lower surfaces different in height from a front surface of the semiconductor substrate.

7. The semiconductor device according to claim 6,
wherein each of the plurality of second electrodes contains at least one material of Ti, Cr, W, and Mo.
